(19) United States
(12) Patent Application Publication
(10) Pub. No.: US 2022/0286138 A1
(43) Pub. Date: Sep. 8, 2022

(54) Phase Locked Loop with Low Reference Spur

(71) Applicant: NVIDIA Corp., Santa Clara, CA (US)

(72) Inventors: Chun-Ju Shen, Los Altos, CA (US); Ying Wei, San Jose, CA (US); Vishnu Balan, Saratoga, CA (US)

(73) Assignee: NVIDIA Corp., Santa Clara, CA (US)

(21) Appl. No.: 17/191,268

(22) Filed: Mar. 3, 2021

(51) Int. Cl. H03L 7/099; H03L 7/089; H03L 7/091

(52) U.S. Cl. CPC H03L 7/0992; H03L 7/0893; H03L 7/091

(57) ABSTRACT

A calibration circuit including multiple charge pumps supplying a voltage controlled oscillator along different paths, one path being an integration path from a first one of the charge pumps to the voltage controlled oscillator, and one path being a proportional path from a second one of the charge pumps to the voltage controlled oscillator. A phase locked loop of the calibration circuit utilizes a switch capacitor circuit to reduce reference spur and improve the accuracy of clock edges for multi-phase calibration.

### BACKGROUND

A conventional clock calibration circuit 100 as depicted in FIG. 1 utilizes a phase locked loop (PLL) to carry out

f(CLKₒᵤₜ)=f(CLKᵢₙ)*FDIV

In some types of PLL, the above condition can be achieved by aligning the phases of CLKᵢₙ and CLK_{fb}. A phase/frequency detector 102 senses the phase difference between CLKᵢₙ and CLK_{fb}, and generates up and down pulses to a charge pump 104 with a pulse width difference (Δt) proportional to the phase difference. Upon receiving the up and down pulses, the charge pump 104 generate a current pulse with height I_{cp} and pulse width Δt. The current pulse updates the control voltage vctrl, which adjusts the frequency and phase of a voltage controlled oscillator 106 output signal, CLKₒᵤₜ, which is divided by a frequency divider 108 to generate CLK_{fb}. The phase difference between CLKᵢₙ and CLKₒᵤₜ is thus influenced by vctrl. When the phase difference between CLKᵢₙ and CLKₒᵤₜ approaches zero, the average value of vctrl is constant, and the PLL loop reaches the steady state. The capacitor 112 acts as an integrator that stores the voltage required for the targeted voltage controlled oscillator 106 output frequency. The resistor 110 stabilizes the PLL loop by improving the loop responsiveness to phase adjustments.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts one type of conventional clock calibration circuit 100.

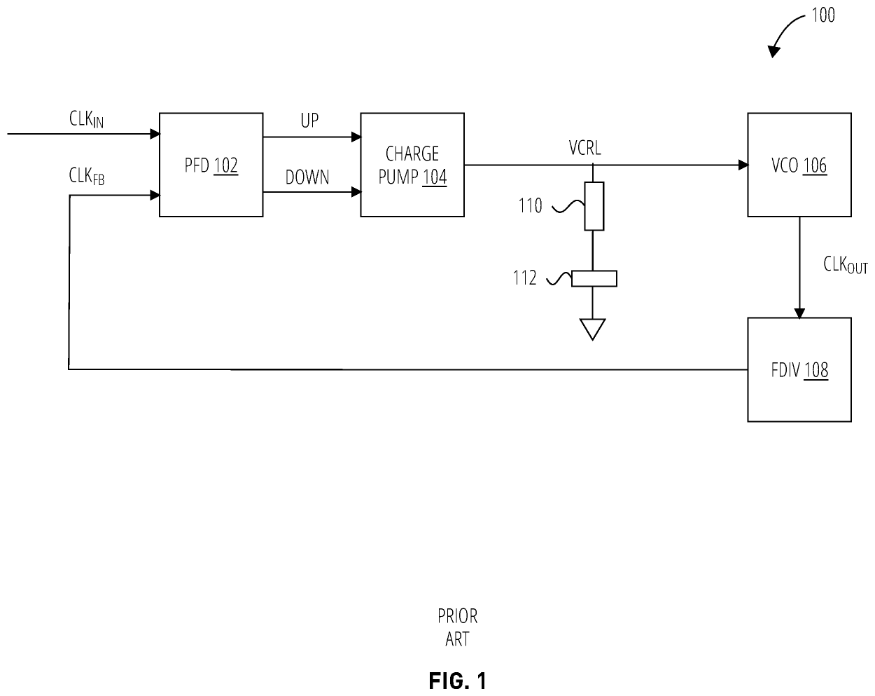

FIG. 2 depicts a circuit system 202 in accordance with one embodiment.

FIG. 3 depicts a data transceiver 300 in accordance with one embodiment.

FIG. 4 illustrates an aspect of the subject matter in accordance with one embodiment.

FIG. 5 depicts a clock calibration circuit 500 in accordance with one embodiment.

FIG. 6 depicts a switched capacitive circuit 600 in accordance with one embodiment.

FIG. 7 depicts a signal timing diagram 700 in accordance with one embodiment.

FIG. 8 depicts a parallel processing unit 1208b in accordance with one embodiment.

FIG. 9 depicts a general processing cluster 900 in accordance with one embodiment.

FIG. 10 depicts a memory partition unit 1000 in accordance with one embodiment.

FIG. 11 depicts a streaming multiprocessor 1100 in accordance with one embodiment.

FIG. 12 depicts a processing system 1200 in accordance with one embodiment.

FIG. 13 depicts an exemplary processing system 1300 in accordance with another embodiment.

FIG. 14 depicts a graphics processing pipeline 1400 in accordance with one embodiment.

FIG. 15 illustrates an aspect of the subject matter in accordance with one embodiment.

### DETAILED DESCRIPTION

The phase/frequency detector and the charge pump of conventional clock calibration circuits may exhibit imperfections such as UP and DOWN pulse skew, width mismatch, and current mismatch. Additional examples of imperfections that may be present are charge injection and clock feedthrough.

These imperfections may generate ripples in the vctrl signal in the time domain, which translate to reference spurs in the frequency domain. The phase/frequency detector and the charge pump operate at the frequency of CLKᵢₙ, causing the reference spurs to have an offset frequency that is an integer multiple of CLKᵢₙ. Reference spurs may exceed the noise floor limit of the implementation and contribute to jitter in the CLKₒᵤₜ signal.

Circuits are herein disclosed to improve the uniformity of spacing between multiple (e.g., eight) signal phases to improve the timing margin of circuits utilizing those signals or, more generally, to reduce the spur in a signal generated from other signals.

In one aspect, a phase locked loop includes a plurality of charge pumps, a voltage controlled oscillator, an integration path from a first one of the charge pumps to the voltage controlled oscillator, and a proportional path from a second one of the charge pumps to the voltage controlled oscillator. The proportional path includes a switched capacitive circuit comprising a parallel configuration of sample and hold switches. A plurality of reset switches couple to inner nodes of the switched capacitive circuit and shunt between the reset switches. (Collectively the sample, hold, and reset configuration may be referred to herein as a “series-parallel configuration of switches). The circuit may also include a reset-sample-hold circuit configured to control the switched capacitive circuit.

A first voltage-to-current converter of the calibration circuit is configured on the integration path, and a second voltage-to-current converter is configured on the proportional path. Outputs of the voltage-to-current converters are merged into a current controlled oscillator.

Although described by example with reference to multi-phase clock calibration, generally the logic described herein may be advantageous to reduce reference spurs, and hence jitter, when generating a sampling or trigger signal for any purpose. Aspects of the circuit may find application in data transceivers, data centers, cars, robots, computer servers and workstations, and in any circuit for which reduction of spurs in an output signal is desirable.

Other technical features may be readily apparent to one skilled in the art from the following figures, descriptions, and claims.

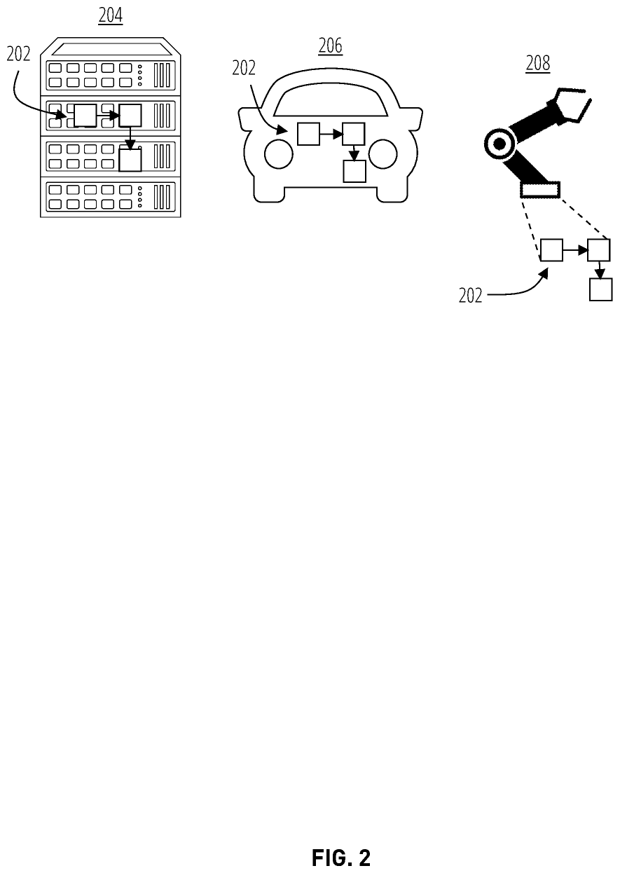

FIG. 2 depicts exemplary scenarios for use of a circuit system 202 in accordance with some embodiments. A circuit system 202 may be utilized in a computing system 204, a vehicle 206, and a robot 208, to name just a few examples. The circuit system 202 may comprise a first digital circuit that generates a signal to a phase locked loop that generates a reference signal to a second digital circuit, e.g., for sampling another signal or for triggering an operation of the second circuit.

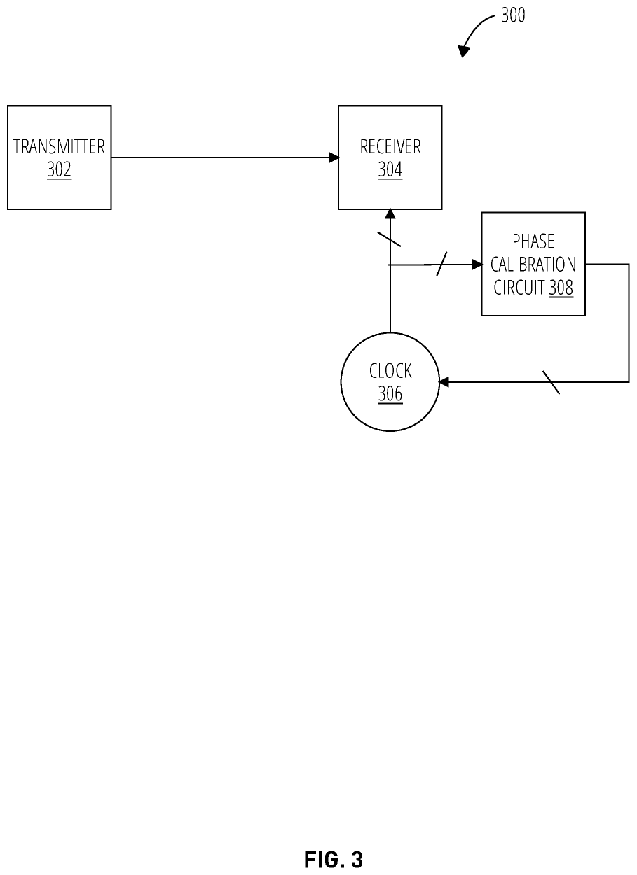

FIG. 3 depicts a data transceiver 300 in one embodiment. The transmitter 302 transmits data signals to the receiver 304. The data signals are synchronized to one or more clock signals. The receiver 304 utilizes a clock 306 (e.g., a multi-phase clock generator) to recover the data signals accurately. A phase calibration circuit 308 is utilized to maintain equal phase shifts between the clock signals from the clock 306.

In one example, the clock 306 may generate a multi-phase (e.g., 8 phase) clock signal to the receiver 304. Although depicted in conjunction with the receiver 304, phase calibration circuit 308 may more generally be utilized by the transmitter 302, the receiver 304, or by both of the transmitter 302 and receiver 304.

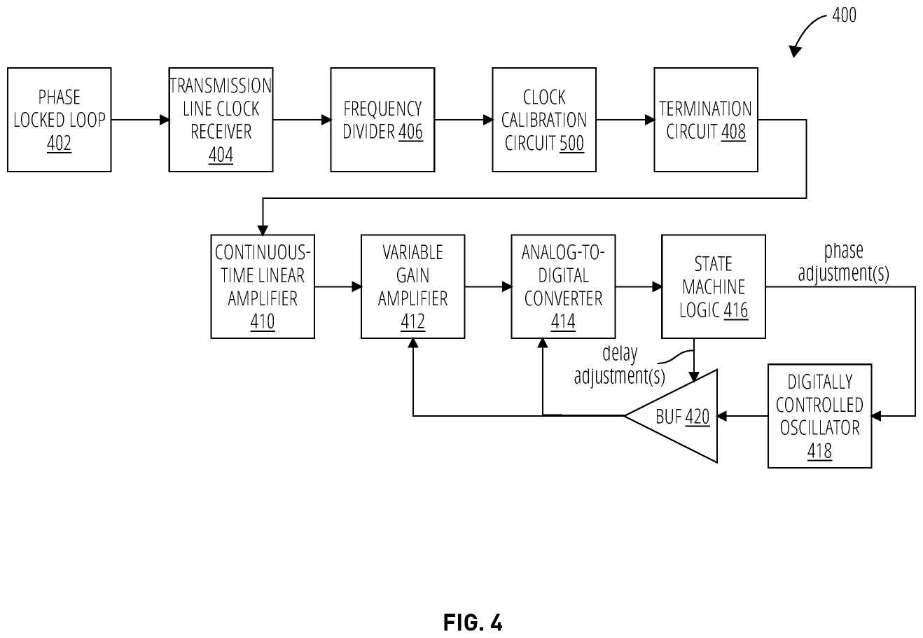

FIG. 4 depicts a clock recovery circuit 400 in one embodiment. A phase locked loop 402 supplies a clock signal (external clock signal) via a transmission line clock receiver 404 to a frequency divider 406 to generate a reference clock signal, (e.g., to 15/8 of the period of the digitally controlled oscillator 418 clock frequency). More generally, the reference clock signal may have a period that is a non-integer multiple of the period of the external clock signal and the digitally controlled oscillator 418 clock signals.

The clock signal passes through a clock calibration circuit 500 and a termination circuit 408 and then through a series of stages including a continuous-time linear amplifier 410, a variable gain amplifier 412, an analog-to-digital converter 414, and state machine logic 416. A multiplexer or other switching circuit may be utilized to bypass the termination circuit 408 during clock calibration, so that the reference clock signal from the clock calibration circuit 500 is applied downstream instead of the external clock signal.

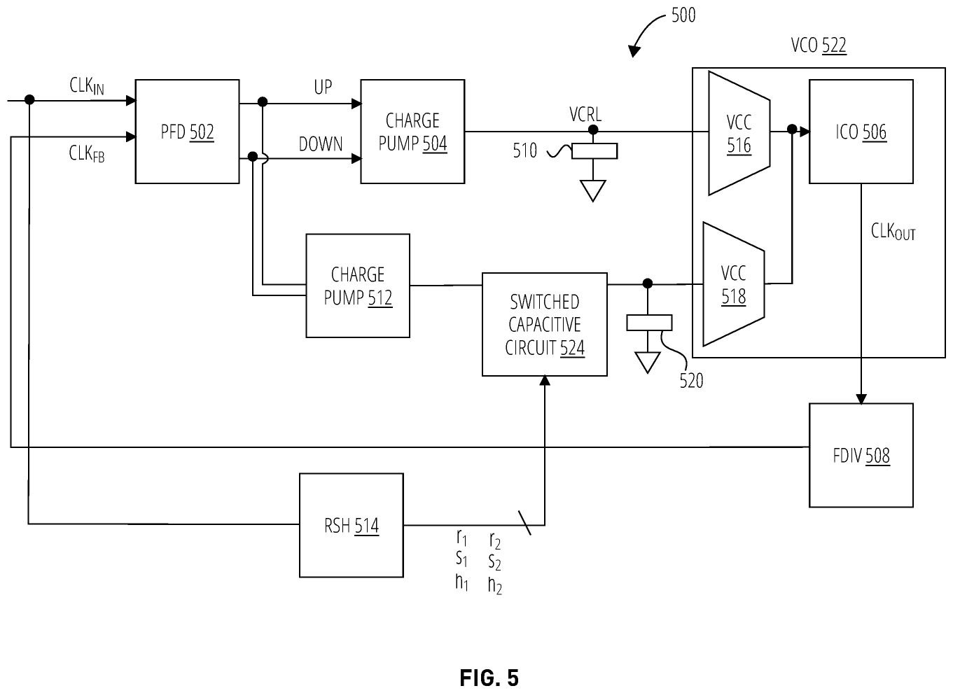

The state machine logic 416 controls a digitally controlled oscillator 418 that provides the recovered clock signal, to adjust the average phase of the multi-phase signal output from the digitally controlled oscillator 418. The state machine logic 416 also provides delay adjustments to the clock delay buffer 420 to control the spacing between the multiple phases of the digitally controlled oscillator 418 output signals. Feedback to variable gain amplifier 412 and analog-to-digital converter 414 may be provided by a (e.g., tunable) clock delay buffer 420. Clock recovery circuits having this general structure and variations of it are known in the art. However the clock recovery circuit 400 utilizes a novel clock calibration circuit 500, depicted in more detail in one embodiment in FIG. 5, to calibrate the phases of the multi-phase clock signal. The output signal of the clock calibration circuit 500 may be applied to sample each clock signal of the multi-phase clock signals generated by the digitally controlled oscillator 418, for example on the rising or falling edges. In one embodiment the clock calibration circuit 500 outputs a signal that is slightly more than (e.g., 8/15 of) ½ the frequency of the digitally controlled oscillator 418 multi-phase clock signals.

FIG. 5 depicts a clock calibration circuit 500 in one embodiment. The output of the clock calibration circuit 500 may be applied to sample each phase of a multi-phase clock, to urge uniform phase spacing between the phases. One example of a circuit that may be utilized to carry out the clock edge sampling is a bang-bang circuit.

A phase locked loop comprising a feedback clock signal CLK_{fb} is configured for a phase/frequency detector 502. A clock signal CLKᵢₙ is provided as an input to this phase locked loop. The phase/frequency detector 502 outputs UP and DOWN signals to a plurality (e.g., two) charge pump circuits (charge pump 504 and charge pump 512 in this example). The charge pumps generate more or less output current as a result of receiving an UP or DOWN signal, respectively. The charge pump 504 drives an integration path comprising capacitor 510 and voltage-to-current converter 516. The charge pump 512 drives a proportional path comprising switched capacitive circuit 524, capacitor 520, and voltage-to-current converter 518. In general, during operation of the clock calibration circuit 500 the currents on the integration path and on the proportional path may have different values, particularly different pulse amplitudes. The output currents of voltage-to-current converter 516 and voltage-to-current converter 518 are added (merged) into a current controlled oscillator 506 of the voltage controlled oscillator 522 comprising the voltage-to-current converter 516 and voltage-to-current converter 518. More generally, different gain circuits (e.g., amplifiers) may be utilized on the proportional path and the integration path. The feedback path of the phase locked loop comprises a frequency divider 508 providing the output CLK_{fb} back to the phase/frequency detector 502.

Those of skill in the art may appreciate that any of a variety of charge pump circuit types known in the art may be utilized. The charge pump 504 and the charge pump 512 may have similar internal circuit structure, or may utilize different circuit topologies, according to the parameters of the implementation. Likewise, any of a variety of circuit designs for phase and frequency detectors, voltage-to-current converters, frequency dividers, and current controlled oscillators may be employed. Capacitors where depicted may in some implementations be replaced with circuits having different structure and components but similar capacitance behavior.

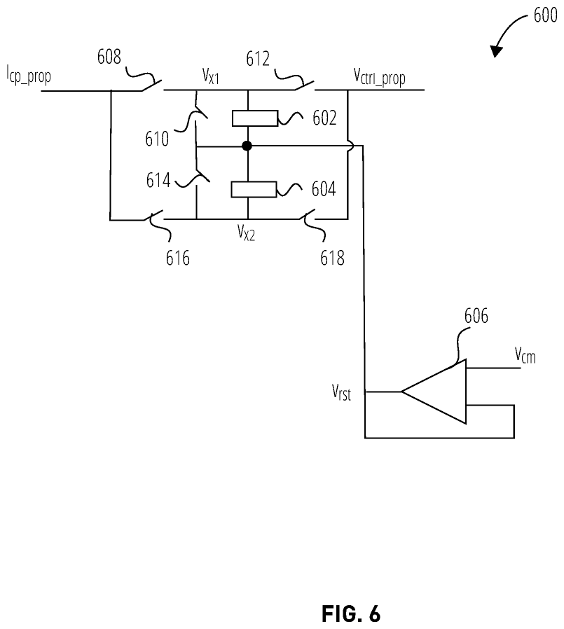

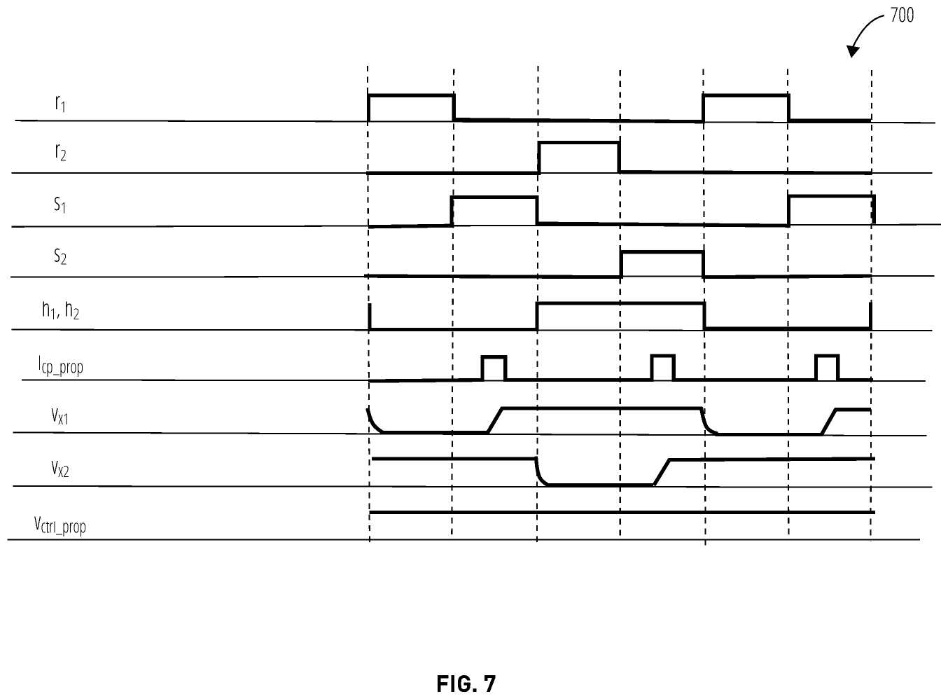

The switched capacitive circuit 524 is operated by reset-sample-hold circuit 514 in manners described in more detail for one embodiment in conjunction with FIG. 6 and FIG. 7.

The s-domain (Laplace frequency) transfer function H(s) of the clock calibration circuit 500 may be expressed as:

$$\frac{{Φ}_{out}}{{Φ}_{i n}} = \frac{{s}^{2} + 2 ζ {ω}_{n} s}{{s}^{2} + 2 ζ {ω}_{n} s + {ω}_{n}^{2}}$$

From the s-domain transfer function, the natural frequency ωₙ and damping factor ζ may be determined for a desired bandwidth, stability (phase margin), and AC peaking. The values for ωₙ and ζ are determined by design parameters such as output currents of the charge pumps, gain of the voltage controlled oscillator 522, division ratio of the frequency divider 508, effective resistance of the switched capacitive circuit 524, and relative gains between the integration path and the proportional path.

The natural frequency may be expressed in terms of the characteristics of the integration path as:

$${w}_{n} = \sqrt{\frac{{I}_{cp}^{*} {K}_{v c o}}{2 π N C}}$$

where I_{cp} is the current on the integration path, K_{vco} is the VCO gain, N is the frequency divider 508 ratio, and C is the capacitance of the integration path (capacitor 510).

The damping factor ζ may be expressed as:

$$ζ = \frac{m r {R}_{eff}}{2} = \sqrt{\frac{{I}_{{cp}^{*}} {K}_{vco}^{*} C}{2 π N}}$$

where m is the ratio of charge pump current on the proportional path to the ratio of charge pump current on the integration path, r is the ratio of voltage-to-current converter gain on the proportional path to the voltage-to-current converter gain on the integration path, and R_{eff} is the effective resistance of the switched capacitive circuit 524.

FIG. 6 depicts a switched capacitive circuit 600 in one embodiment. The switched capacitive circuit 600 comprises sample switch s₁ 608, a reset switch r₁ 610, and a hold switch h₁ 612. The switched capacitive circuit 600 further comprises a reset switch r₂ 614, a sample switch s₂ 616, and a hold switch h₂ 618. The switched capacitive circuit 600 also includes a capacitor 602, a capacitor 604, and a comparator 606. Each cycle of the switched capacitive circuit 600 converts the current pulse I_{cp_prop} into a DC voltage v_{ctrl_prop}.

The equivalent resistance of the switched capacitive circuit 524 is determined by the capacitances (capacitor 602 and capacitor 604) and the period of the pulses from the charge pump 512. Vrst is the reset voltage and v_{cm} is the common mode voltage for the switched capacitive circuit 600 (these may be set according to the design requirements).

Exemplary signals for driving the reset switches, sample switches, and hold switches are depicted in the signal timing diagram 700 of FIG. 7. The hold signals h₁ and h₂ are complementary, so only one waveform is depicted. In the reset phase, two terminals of each of the capacitors are reset to vᵣₛₜ, which is a buffered version of the common mode voltage v_{cm}. V_{cm} may be set based on a desired operation point of the charge pump 512, voltage-to-current converter 516, and voltage-to-current converter 518. In the sample phase, either of vₓ₁ or vₓ₂ are updated by the charge pump 512 current pulse. In the hold phase, v_{ctrl_prop} is connected to one of the capacitors that holds the stable voltage. Capacitor 520 suppresses any clock-feedthrough noise from hold switch h₁ 612 and hold switch h₂ 618 toggling.

Once the phase locked loop of the clock calibration circuit 500 is locked, the current pulse I_{cp_prop} is periodic and therefore v_{ctrl_prop} stabilizes to a DC voltage with no reference spur. This property holds even if the charge pump 512 has imperfections such as up/down current mismatch, clock feedthrough, charge injection, and UP/DOWN pulse mismatch.

In the clock calibration circuit 500 utilizing the switched capacitive circuit 600 there is no requirement to equalize the delay of two charge pump paths and there is no contention between competing phase locked loops.

Those of skill in the art may appreciate that the switched capacitive circuit 600 may be readily implemented with more than two sample and hold stages, e.g., with a third stage and third capacitor, and so on, depending on design parameters such as the response time, equivalent resistance, and output current of the charge pump 512 that affect the timing of the sample and hold switches.

Embodiments of the circuits disclosed herein may be executed by computing devices utilizing one or more graphic processing unit (GPU) and/or general purpose data processor (e.g., a ‘central processing unit or CPU). Exemplary architectures will now be described that may be configured to carry out the techniques disclosed herein on such devices.

The following description may use certain acronyms and abbreviations as follows:

“DPC” refers to a “data processing cluster”;

“GPC” refers to a “general processing cluster”;

“I/O” refers to a “input/output”;

“L1 cache” refers to “level one cache”;

“L2 cache” refers to “level two cache”;

“LSU” refers to a “load/store unit”;

“MMU” refers to a “memory management unit”;

“MPC” refers to an “M-pipe controller”;

“PPU” refers to a “parallel processing unit”;

“PROP” refers to a “pre-raster operations unit”;

“ROP” refers to a “raster operations”;

“SFU” refers to a “special function unit”;

“SM” refers to a “streaming multiprocessor”;

“Viewport SCC” refers to “viewport scale, cull, and clip”;

“WDX” refers to a “work distribution crossbar”; and

“XBar” refers to a “crossbar”.

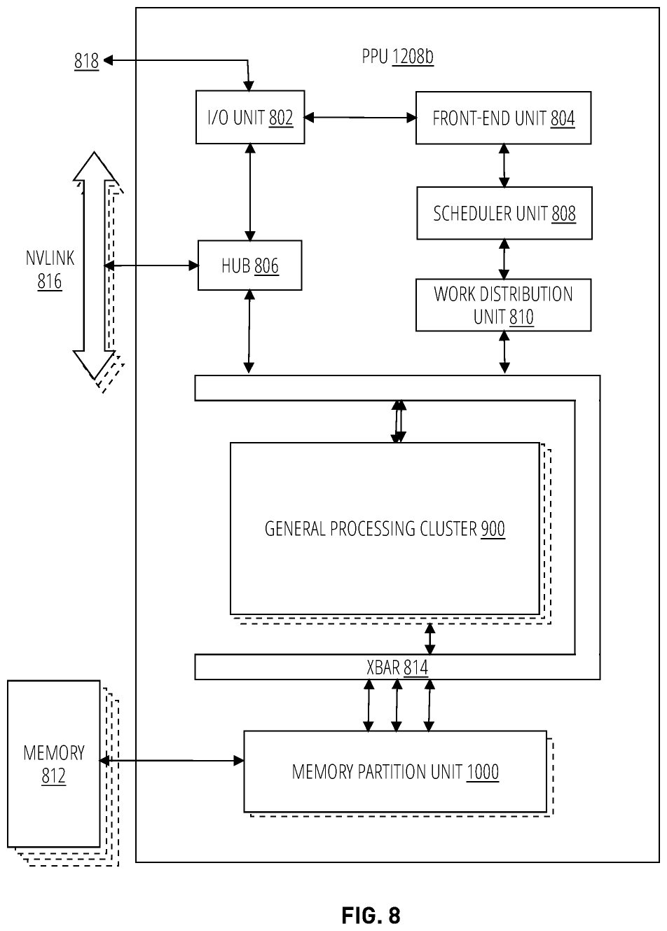

FIG. 8 depicts a parallel processing unit 1208b, in accordance with an embodiment. In an embodiment, the parallel processing unit 1208b is a multi-threaded processor that is implemented on one or more integrated circuit devices. The parallel processing unit 1208b is a latency hiding architecture designed to process many threads in parallel. A thread (e.g., a thread of execution) is an instantiation of a set of instructions configured to be executed by the parallel processing unit 1208b. In an embodiment, the parallel processing unit 1208b is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 1208b may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 1208b modules may be configured to accelerate thousands of High Performance Computing (HPC), data center, and machine learning applications. The parallel processing unit 1208b may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 8, the parallel processing unit 1208b includes an I/O unit 802, a front-end unit 804, a scheduler unit 808, a work distribution unit 810, a hub 806, a crossbar 814, one or more general processing cluster 900 modules, and one or more memory partition unit 1000 modules. The parallel processing unit 1208b may be connected to a host processor or other parallel processing unit 1208b modules via one or more high-speed NVLink 816 interconnects. The parallel processing unit 1208b may be connected to a host processor or other peripheral devices via an interconnect 818. The parallel processing unit 1208b may also be connected to a local memory comprising a number of memory 812 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 812 may comprise logic to configure the parallel processing unit 1208b to carry out aspects of the techniques disclosed herein.

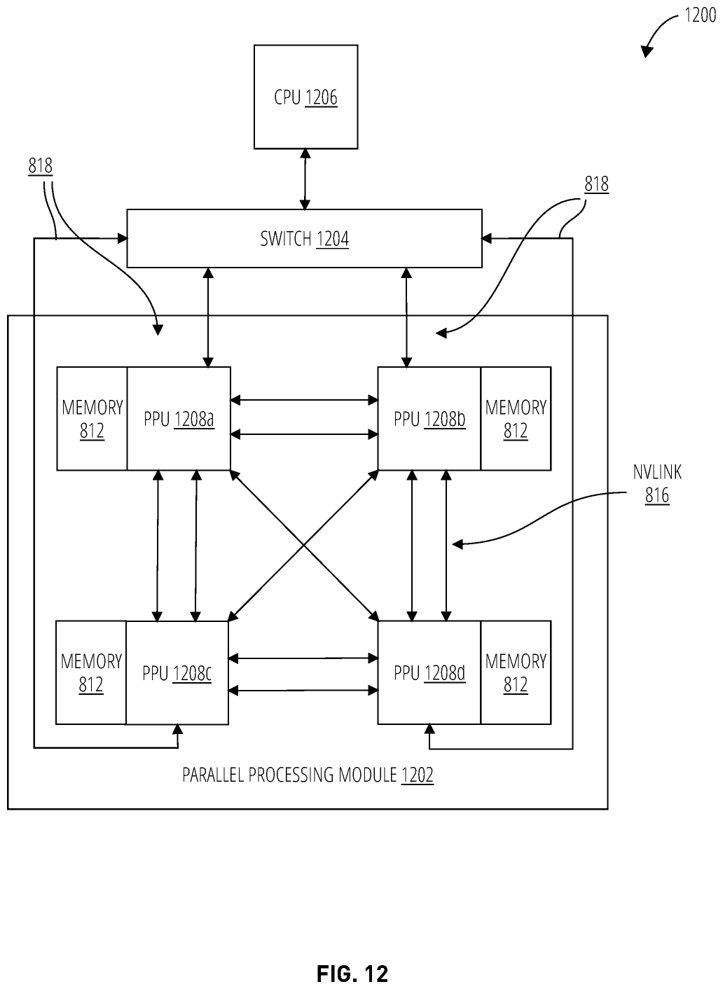

The NVLink 816 interconnect enables systems to scale and include one or more parallel processing unit 1208b modules combined with one or more CPUs, supports cache coherence between the parallel processing unit 1208b modules and CPUs, and CPU mastering. Data and/or commands may be transmitted by the NVLink 816 through the hub 806 to/from other units of the parallel processing unit 1208b such as one or more copy engines, a video encoder, a video decoder, a power management unit, etc. (not explicitly shown). The NVLink 816 is described in more detail in conjunction with FIG. 12.

The I/O unit 802 is configured to transmit and receive communications (e.g., commands, data, etc.) from a host processor (not shown) over the interconnect 818. The I/O unit 802 may communicate with the host processor directly via the interconnect 818 or through one or more intermediate devices such as a memory bridge. In an embodiment, the I/O unit 802 may communicate with one or more other processors, such as one or more parallel processing unit 1208b modules via the interconnect 818. In an embodiment, the I/O unit 802 implements a Peripheral Component Interconnect Express (PCIe) interface for communications over a PCIe bus and the interconnect 818 is a PCIe bus. In alternative embodiments, the I/O unit 802 may implement other types of well-known interfaces for communicating with external devices.

The I/O unit 802 decodes packets received via the interconnect 818. In an embodiment, the packets represent commands configured to cause the parallel processing unit 1208b to perform various operations. The I/O unit 802 transmits the decoded commands to various other units of the parallel processing unit 1208b as the commands may specify. For example, some commands may be transmitted to the front-end unit 804. Other commands may be transmitted to the hub 806 or other units of the parallel processing unit 1208b such as one or more copy engines, a video encoder, a video decoder, a power management unit, etc. (not explicitly shown). In other words, the I/O unit 802 is configured to route communications between and among the various logical units of the parallel processing unit 1208b.

In an embodiment, a program executed by the host processor encodes a command stream in a buffer that provides workloads to the parallel processing unit 1208b for processing. A workload may comprise several instructions and data to be processed by those instructions. The buffer is a region in a memory that is accessible (e.g., read/write) by both the host processor and the parallel processing unit 1208b. For example, the I/O unit 802 may be configured to access the buffer in a system memory connected to the interconnect 818 via memory requests transmitted over the interconnect 818. In an embodiment, the host processor writes the command stream to the buffer and then transmits a pointer to the start of the command stream to the parallel processing unit 1208b. The front-end unit 804 receives pointers to one or more command streams. The front-end unit 804 manages the one or more streams, reading commands from the streams and forwarding commands to the various units of the parallel processing unit 1208b.

The front-end unit 804 is coupled to a scheduler unit 808 that configures the various general processing cluster 900 modules to process tasks defined by the one or more streams. The scheduler unit 808 is configured to track state information related to the various tasks managed by the scheduler unit 808. The state may indicate which general processing cluster 900 a task is assigned to, whether the task is active or inactive, a priority level associated with the task, and so forth. The scheduler unit 808 manages the execution of a plurality of tasks on the one or more general processing cluster 900 modules.

The scheduler unit 808 is coupled to a work distribution unit 810 that is configured to dispatch tasks for execution on the general processing cluster 900 modules. The work distribution unit 810 may track a number of scheduled tasks received from the scheduler unit 808. In an embodiment, the work distribution unit 810 manages a pending task pool and an active task pool for each of the general processing cluster 900 modules. The pending task pool may comprise a number of slots (e.g., 32 slots) that contain tasks assigned to be processed by a particular general processing cluster 900. The active task pool may comprise a number of slots (e.g., 4 slots) for tasks that are actively being processed by the general processing cluster 900 modules. As a general processing cluster 900 finishes the execution of a task, that task is evicted from the active task pool for the general processing cluster 900 and one of the other tasks from the pending task pool is selected and scheduled for execution on the general processing cluster 900. If an active task has been idle on the general processing cluster 900, such as while waiting for a data dependency to be resolved, then the active task may be evicted from the general processing cluster 900 and returned to the pending task pool while another task in the pending task pool is selected and scheduled for execution on the general processing cluster 900.

The work distribution unit 810 communicates with the one or more general processing cluster 900 modules via crossbar 814. The crossbar 814 is an interconnect network that couples many of the units of the parallel processing unit 1208b to other units of the parallel processing unit 1208b. For example, the crossbar 814 may be configured to couple the work distribution unit 810 to a particular general processing cluster 900. Although not shown explicitly, one or more other units of the parallel processing unit 1208b may also be connected to the crossbar 814 via the hub 806.

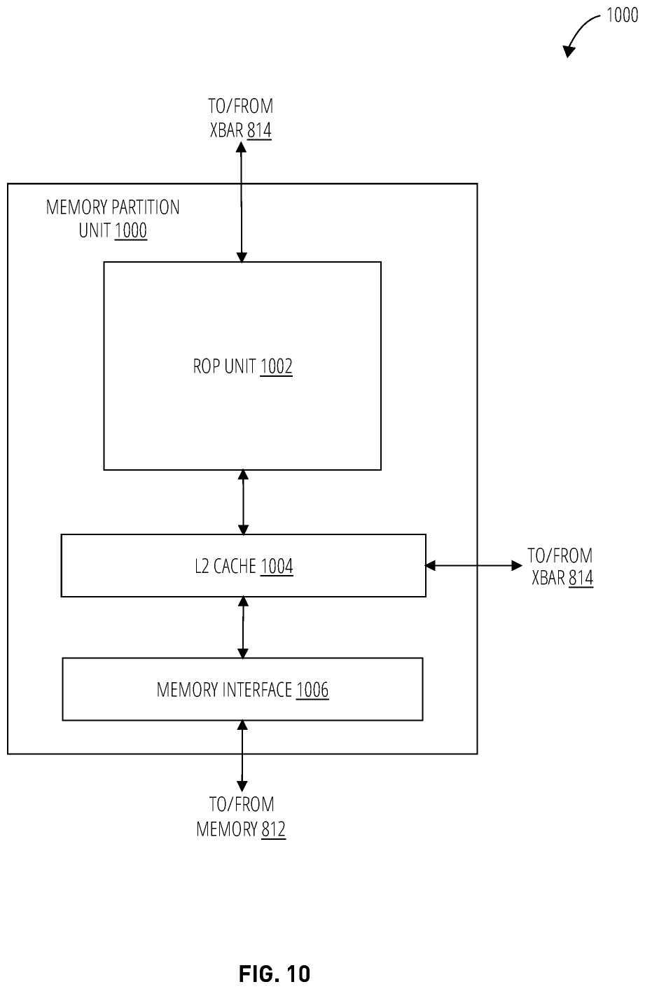

The tasks are managed by the scheduler unit 808 and dispatched to a general processing cluster 900 by the work distribution unit 810. The general processing cluster 900 is configured to process the task and generate results. The results may be consumed by other tasks within the general processing cluster 900, routed to a different general processing cluster 900 via the crossbar 814, or stored in the memory 812. The results can be written to the memory 812 via the memory partition unit 1000 modules, which implement a memory interface for reading and writing data to/from the memory 812. The results can be transmitted to another parallel processing unit 1208b or CPU via the NVLink 816. In an embodiment, the parallel processing unit 1208b includes a number U of memory partition unit 1000 modules that is equal to the number of separate and distinct memory 812 devices coupled to the parallel processing unit 1208b. A memory partition unit 1000 will be described in more detail below in conjunction with FIG. 10.

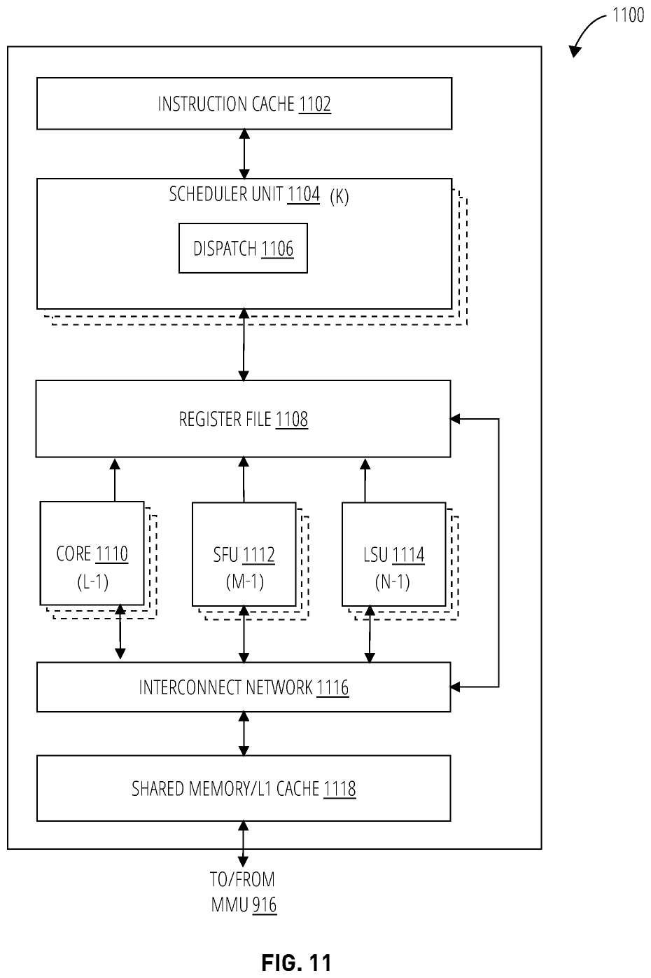

In an embodiment, a host processor executes a driver kernel that implements an application programming interface (API) that enables one or more applications executing on the host processor to schedule operations for execution on the parallel processing unit 1208b. In an embodiment, multiple compute applications are simultaneously executed by the parallel processing unit 1208b and the parallel processing unit 1208b provides isolation, quality of service (QoS), and independent address spaces for the multiple compute applications. An application may generate instructions (e.g., API calls) that cause the driver kernel to generate one or more tasks for execution by the parallel processing unit 1208b. The driver kernel outputs tasks to one or more streams being processed by the parallel processing unit 1208b. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 11.

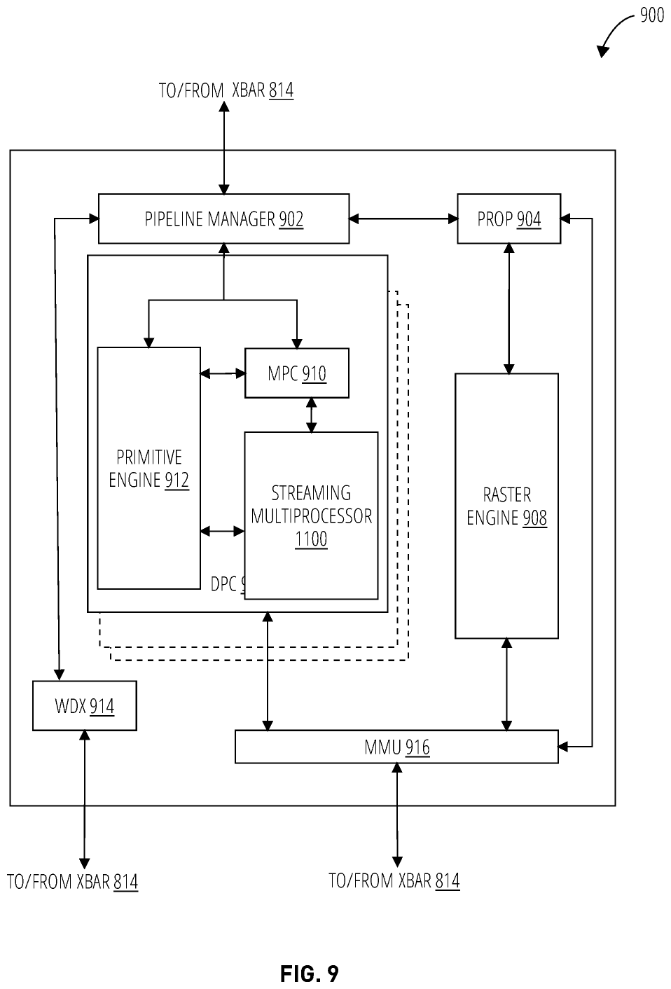

FIG. 9 depicts a general processing cluster 900 of the parallel processing unit 1208b of FIG. 8, in accordance with an embodiment. As shown in FIG. 9, each general processing cluster 900 includes a number of hardware units for processing tasks. In an embodiment, each general processing cluster 900 includes a pipeline manager 902, a pre-raster operations unit 904, a raster engine 908, a work distribution crossbar 914, a memory management unit 916, and one or more data processing cluster 906. It will be appreciated that the general processing cluster 900 of FIG. 9 may include other hardware units in lieu of or in addition to the units shown in FIG. 9.

In an embodiment, the operation of the general processing cluster 900 is controlled by the pipeline manager 902. The pipeline manager 902 manages the configuration of the one or more data processing cluster 906 modules for processing tasks allocated to the general processing cluster 900. In an embodiment, the pipeline manager 902 may configure at least one of the one or more data processing cluster 906 modules to implement at least a portion of a graphics rendering pipeline. For example, a data processing cluster 906 may be configured to execute a vertex shader program on the programmable streaming multiprocessor 1100. The pipeline manager 902 may also be configured to route packets received from the work distribution unit 810 to the appropriate logical units within the general processing cluster 900. For example, some packets may be routed to fixed function hardware units in the pre-raster operations unit 904 and/or raster engine 908 while other packets may be routed to the data processing cluster 906 modules for processing by the primitive engine 912 or the streaming multiprocessor 1100. In an embodiment, the pipeline manager 902 may configure at least one of the one or more data processing cluster 906 modules to implement a neural network model and/or a computing pipeline.

The pre-raster operations unit 904 is configured to route data generated by the raster engine 908 and the data processing cluster 906 modules to a Raster Operations (ROP) unit, described in more detail in conjunction with FIG. 10. The pre-raster operations unit 904 may also be configured to perform optimizations for color blending, organize pixel data, perform address translations, and the like.

The raster engine 908 includes a number of fixed function hardware units configured to perform various raster operations. In an embodiment, the raster engine 908 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x, y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 908 comprises fragments to be processed, for example, by a fragment shader implemented within a data processing cluster 906.

Each data processing cluster 906 included in the general processing cluster 900 includes an M-pipe controller 910, a primitive engine 912, and one or more streaming multiprocessor 1100 modules. The M-pipe controller 910 controls the operation of the data processing cluster 906, routing packets received from the pipeline manager 902 to the appropriate units in the data processing cluster 906. For example, packets associated with a vertex may be routed to the primitive engine 912, which is configured to fetch vertex attributes associated with the vertex from the memory 812. In contrast, packets associated with a shader program may be transmitted to the streaming multiprocessor 1100.

The streaming multiprocessor 1100 comprises a programmable streaming processor that is configured to process tasks represented by a number of threads. Each streaming multiprocessor 1100 is multi-threaded and configured to execute a plurality of threads (e.g., 32 threads) from a particular group of threads concurrently. In an embodiment, the streaming multiprocessor 1100 implements a Single-Instruction, Multiple-Data (SIMD) architecture where each thread in a group of threads (e.g., a warp) is configured to process a different set of data based on the same set of instructions. All threads in the group of threads execute the same instructions. In another embodiment, the streaming multiprocessor 1100 implements a Single-Instruction, Multiple Thread (SIMT) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The streaming multiprocessor 1100 will be described in more detail below in conjunction with FIG. 11.

The memory management unit 916 provides an interface between the general processing cluster 900 and the memory partition unit 1000. The memory management unit 916 may provide translation of virtual addresses into physical addresses, memory protection, and arbitration of memory requests. In an embodiment, the memory management unit 916 provides one or more translation lookaside buffers (TLBs) for performing translation of virtual addresses into physical addresses in the memory 812.

FIG. 10 depicts a memory partition unit 1000 of the parallel processing unit 1208b of FIG. 8, in accordance with an embodiment. As shown in FIG. 10, the memory partition unit 1000 includes a raster operations unit 1002, a level two cache 1004, and a memory interface 1006. The memory interface 1006 is coupled to the memory 812. Memory interface 1006 may implement 32, 64, 128, 1024-bit data buses, or the like, for high-speed data transfer. In an embodiment, the parallel processing unit 1208b incorporates U memory interface 1006 modules, one memory interface 1006 per pair of memory partition unit 1000 modules, where each pair of memory partition unit 1000 modules is connected to a corresponding memory 812 device. For example, parallel processing unit 1208b may be connected to up to Y memory 812 devices, such as high bandwidth memory stacks or graphics double-data-rate, version 5, synchronous dynamic random access memory, or other types of persistent storage.

In an embodiment, the memory interface 1006 implements an HBM2 memory interface and Y equals half U. In an embodiment, the HBM2 memory stacks are located on the same physical package as the parallel processing unit 1208b, providing substantial power and area savings compared with conventional GDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 812 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where parallel processing unit 1208b modules process very large datasets and/or run applications for extended periods.

In an embodiment, the parallel processing unit 1208b implements a multi-level memory hierarchy. In an embodiment, the memory partition unit 1000 supports a unified memory to provide a single unified virtual address space for CPU and parallel processing unit 1208b memory, enabling data sharing between virtual memory systems. In an embodiment the frequency of accesses by a parallel processing unit 1208b to memory located on other processors is traced to ensure that memory pages are moved to the physical memory of the parallel processing unit 1208b that is accessing the pages more frequently. In an embodiment, the NVLink 816 supports address translation services allowing the parallel processing unit 1208b to directly access a CPU's page tables and providing full access to CPU memory by the parallel processing unit 1208b.

In an embodiment, copy engines transfer data between multiple parallel processing unit 1208b modules or between parallel processing unit 1208b modules and CPUs. The copy engines can generate page faults for addresses that are not mapped into the page tables. The memory partition unit 1000 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 812 or other system memory may be fetched by the memory partition unit 1000 and stored in the level two cache 1004, which is located on-chip and is shared between the various general processing cluster 900 modules. As shown, each memory partition unit 1000 includes a portion of the level two cache 1004 associated with a corresponding memory 812 device. Lower level caches may then be implemented in various units within the general processing cluster 900 modules. For example, each of the streaming multiprocessor 1100 modules may implement an L1 cache. The L1 cache is private memory that is dedicated to a particular streaming multiprocessor 1100. Data from the level two cache 1004 may be fetched and stored in each of the L1 caches for processing in the functional units of the streaming multiprocessor 1100 modules. The level two cache 1004 is coupled to the memory interface 1006 and the crossbar 814.

The raster operations unit 1002 performs graphics raster operations related to pixel color, such as color compression, pixel blending, and the like. The raster operations unit 1002 also implements depth testing in conjunction with the raster engine 908, receiving a depth for a sample location associated with a pixel fragment from the culling engine of the raster engine 908. The depth is tested against a corresponding depth in a depth buffer for a sample location associated with the fragment. If the fragment passes the depth test for the sample location, then the raster operations unit 1002 updates the depth buffer and transmits a result of the depth test to the raster engine 908. It will be appreciated that the number of partition memory partition unit 1000 modules may be different than the number of general processing cluster 900 modules and, therefore, each raster operations unit 1002 may be coupled to each of the general processing cluster 900 modules. The raster operations unit 1002 tracks packets received from the different general processing cluster 900 modules and determines which general processing cluster 900 that a result generated by the raster operations unit 1002 is routed to through the crossbar 814. Although the raster operations unit 1002 is included within the memory partition unit 1000 in FIG. 10, in other embodiment, the raster operations unit 1002 may be outside of the memory partition unit 1000. For example, the raster operations unit 1002 may reside in the general processing cluster 900 or another unit.

FIG. 11 illustrates the streaming multiprocessor 1100 of FIG. 9, in accordance with an embodiment. As shown in FIG. 11, the streaming multiprocessor 1100 includes an instruction cache 1102, one or more scheduler unit 1104 modules (e.g., such as scheduler unit 808), a register file 1108, one or more processing core 1110 modules, one or more special function unit 1112 modules, one or more load/store unit 1114 modules, an interconnect network 1116, and a shared memory/L1 cache 1118.

As described above, the work distribution unit 810 dispatches tasks for execution on the general processing cluster 900 modules of the parallel processing unit 1208b. The tasks are allocated to a particular data processing cluster 906 within a general processing cluster 900 and, if the task is associated with a shader program, the task may be allocated to a streaming multiprocessor 1100. The scheduler unit 808 receives the tasks from the work distribution unit 810 and manages instruction scheduling for one or more thread blocks assigned to the streaming multiprocessor 1100. The scheduler unit 1104 schedules thread blocks for execution as warps of parallel threads, where each thread block is allocated at least one warp. In an embodiment, each warp executes 32 threads. The scheduler unit 1104 may manage a plurality of different thread blocks, allocating the warps to the different thread blocks and then dispatching instructions from the plurality of different cooperative groups to the various functional units (e.g., core 1110 modules, special function unit 1112 modules, and load/store unit 1114 modules) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch 1106 unit is configured within the scheduler unit 1104 to transmit instructions to one or more of the functional units. In one embodiment, the scheduler unit 1104 includes two dispatch 1106 units that enable two different instructions from the same warp to be dispatched during each clock cycle. In alternative embodiments, each scheduler unit 1104 may include a single dispatch 1106 unit or additional dispatch 1106 units.

Each streaming multiprocessor 1100 includes a register file 1108 that provides a set of registers for the functional units of the streaming multiprocessor 1100. In an embodiment, the register file 1108 is divided between each of the functional units such that each functional unit is allocated a dedicated portion of the register file 1108. In another embodiment, the register file 1108 is divided between the different warps being executed by the streaming multiprocessor 1100. The register file 1108 provides temporary storage for operands connected to the data paths of the functional units.

Each streaming multiprocessor 1100 comprises L processing core 1110 modules. In an embodiment, the streaming multiprocessor 1100 includes a large number (e.g., 128, etc.) of distinct processing core 1110 modules. Each core 1110 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the core 1110 modules include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the core 1110 modules. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each streaming multiprocessor 1100 also comprises M special function unit 1112 modules that perform special functions (e.g., attribute evaluation, reciprocal square root, and the like). In an embodiment, the special function unit 1112 modules may include a tree traversal unit configured to traverse a hierarchical tree data structure. In an embodiment, the special function unit 1112 modules may include texture unit configured to perform texture map filtering operations. In an embodiment, the texture units are configured to load texture maps (e.g., a 2D array of texels) from the memory 812 and sample the texture maps to produce sampled texture values for use in shader programs executed by the streaming multiprocessor 1100. In an embodiment, the texture maps are stored in the shared memory/L1 cache 1118. The texture units implement texture operations such as filtering operations using mip-maps (e.g., texture maps of varying levels of detail). In an embodiment, each streaming multiprocessor 1100 includes two texture units.

Each streaming multiprocessor 1100 also comprises N load/store unit 1114 modules that implement load and store operations between the shared memory/L1 cache 1118 and the register file 1108. Each streaming multiprocessor 1100 includes an interconnect network 1116 that connects each of the functional units to the register file 1108 and the load/store unit 1114 to the register file 1108 and shared memory/L1 cache 1118. In an embodiment, the interconnect network 1116 is a crossbar that can be configured to connect any of the functional units to any of the registers in the register file 1108 and connect the load/store unit 1114 modules to the register file 1108 and memory locations in shared memory/L1 cache 1118.

The shared memory/L1 cache 1118 is an array of on-chip memory that allows for data storage and communication between the streaming multiprocessor 1100 and the primitive engine 912 and between threads in the streaming multiprocessor 1100. In an embodiment, the shared memory/L1 cache 1118 comprises 128 KB of storage capacity and is in the path from the streaming multiprocessor 1100 to the memory partition unit 1000. The shared memory/L1 cache 1118 can be used to cache reads and writes. One or more of the shared memory/L1 cache 1118, level two cache 1004, and memory 812 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 1118 enables the shared memory/L1 cache 1118 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 8, are bypassed, creating a much simpler programming model. In the general purpose parallel computation configuration, the work distribution unit 810 assigns and distributes blocks of threads directly to the data processing cluster 906 modules. The threads in a block execute the same program, using a unique thread ID in the calculation to ensure each thread generates unique results, using the streaming multiprocessor 1100 to execute the program and perform calculations, shared memory/L1 cache 1118 to communicate between threads, and the load/store unit 1114 to read and write global memory through the shared memory/L1 cache 1118 and the memory partition unit 1000. When configured for general purpose parallel computation, the streaming multiprocessor 1100 can also write commands that the scheduler unit 808 can use to launch new work on the data processing cluster 906 modules.

The parallel processing unit 1208b may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 1208b is embodied on a single semiconductor substrate. In another embodiment, the parallel processing unit 1208b is included in a system-on-a-chip (SoC) along with one or more other devices such as additional parallel processing unit 1208b modules, the memory 812, a reduced instruction set computer (RISC) CPU, a memory management unit (MMU), a digital-to-analog converter (DAC), and the like.

In an embodiment, the parallel processing unit 1208b may be included on a graphics card that includes one or more memory devices. The graphics card may be configured to interface with a PCIe slot on a motherboard of a desktop computer. In yet another embodiment, the parallel processing unit 1208b may be an integrated graphics processing unit (iGPU) or parallel processor included in the chipset of the motherboard.

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 12 is a conceptual diagram of a processing system 1200 implemented using the parallel processing unit 1208b of FIG. 8, in accordance with an embodiment. The processing system 1200 includes a central processing unit 1206, switch 1204, and multiple parallel processing unit 1208b modules each and respective memory 812 modules. The NVLink 816 provides high-speed communication links between each of the parallel processing unit 1208b modules. Although a particular number of NVLink 816 and interconnect 818 connections are illustrated in FIG. 12, the number of connections to each parallel processing unit 1208b and the central processing unit 1206 may vary. The switch 1204 interfaces between the interconnect 818 and the central processing unit 1206. The parallel processing unit 1208b modules, memory 812 modules, and NVLink 816 connections may be situated on a single semiconductor platform to form a parallel processing module 1202. In an embodiment, the switch 1204 supports two or more protocols to interface between various different connections and/or links.

In another embodiment (not shown), the NVLink 816 provides one or more high-speed communication links between each of the parallel processing unit modules (parallel processing unit 1208a, parallel processing unit 1208b, parallel processing unit 1208c, and parallel processing unit 1208d) and the central processing unit 1206 and the switch 1204 interfaces between the interconnect 818 and each of the parallel processing unit modules. The parallel processing unit modules, memory 812 modules, and interconnect 818 may be situated on a single semiconductor platform to form a parallel processing module 1202. In yet another embodiment (not shown), the interconnect 818 provides one or more communication links between each of the parallel processing unit modules and the central processing unit 1206 and the switch 1204 interfaces between each of the parallel processing unit modules using the NVLink 816 to provide one or more high-speed communication links between the parallel processing unit modules. In another embodiment (not shown), the NVLink 816 provides one or more high-speed communication links between the parallel processing unit modules and the central processing unit 1206 through the switch 1204. In yet another embodiment (not shown), the interconnect 818 provides one or more communication links between each of the parallel processing unit modules directly. One or more of the NVLink 816 high-speed communication links may be implemented as a physical NVLink interconnect or either an on-chip or on-die interconnect using the same protocol as the NVLink 816.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 1202 may be implemented as a circuit board substrate and each of the parallel processing unit modules and/or memory 812 modules may be packaged devices. In an embodiment, the central processing unit 1206, switch 1204, and the parallel processing module 1202 are situated on a single semiconductor platform.

In an embodiment, the signaling rate of each NVLink 816 is 20 to 25 Gigabits/second and each parallel processing unit module includes six NVLink 816 interfaces (as shown in FIG. 12, five NVLink 816 interfaces are included for each parallel processing unit module). Each NVLink 816 provides a data transfer rate of 25 Gigabytes/second in each direction, with six links providing 300 Gigabytes/second. The NVLink 816 can be used exclusively for PPU-to-PPU communication as shown in FIG. 12, or some combination of PPU-to-PPU and PPU-to-CPU, when the central processing unit 1206 also includes one or more NVLink 816 interfaces.

In an embodiment, the NVLink 816 allows direct load/store/atomic access from the central processing unit 1206 to each parallel processing unit module's memory 812. In an embodiment, the NVLink 816 supports coherency operations, allowing data read from the memory 812 modules to be stored in the cache hierarchy of the central processing unit 1206, reducing cache access latency for the central processing unit 1206. In an embodiment, the NVLink 816 includes support for Address Translation Services (ATS), enabling the parallel processing unit module to directly access page tables within the central processing unit 1206. One or more of the NVLink 816 may also be configured to operate in a low-power mode.

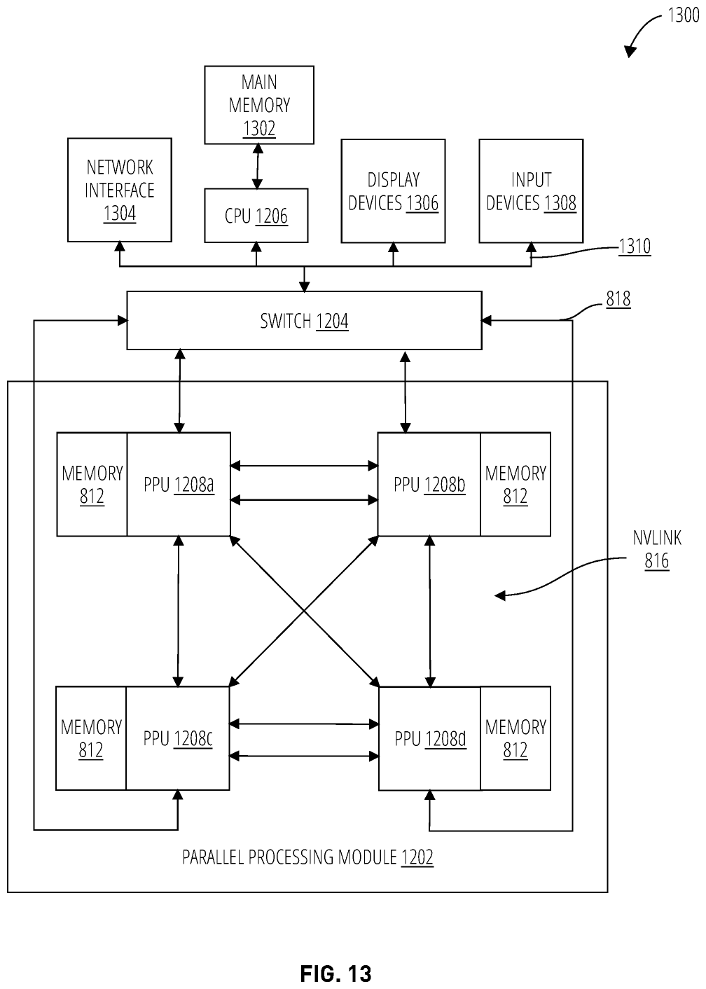

FIG. 13 depicts an exemplary processing system 1300 in which the various architecture and/or functionality of the various previous embodiments may be implemented. As shown, an exemplary processing system 1300 is provided including at least one central processing unit 1206 that is connected to a communications bus 1310. The communication communications bus 1310 may be implemented using any suitable protocol, such as PCI (Peripheral Component Interconnect), PCI-Express, AGP (Accelerated Graphics Port), HyperTransport, or any other bus or point-to-point communication protocol(s). The exemplary processing system 1300 also includes a main memory 1302. Control logic (software) and data are stored in the main memory 1302 which may take the form of random access memory (RAM).

The exemplary processing system 1300 also includes input devices 1308, the parallel processing module 1202, and display devices 1306, e.g. a conventional CRT (cathode ray tube), LCD (liquid crystal display), LED (light emitting diode), plasma display or the like. User input may be received from the input devices 1308, e.g., keyboard, mouse, touchpad, microphone, and the like. Each of the foregoing modules and/or devices may even be situated on a single semiconductor platform to form the exemplary processing system 1300. Alternately, the various modules may also be situated separately or in various combinations of semiconductor platforms per the desires of the user.

Further, the exemplary processing system 1300 may be coupled to a network (e.g., a telecommunications network, local area network (LAN), wireless network, wide area network (WAN) such as the Internet, peer-to-peer network, cable network, or the like) through a network interface 1304 for communication purposes.

The exemplary processing system 1300 may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 1302 and/or the secondary storage. Such computer programs, when executed, enable the exemplary processing system 1300 to perform various functions. The main memory 1302, the storage, and/or any other storage are possible examples of computer-readable media.

The architecture and/or functionality of the various previous figures may be implemented in the context of a general computer system, a circuit board system, a game console system dedicated for entertainment purposes, an application-specific system, and/or any other desired system. For example, the exemplary processing system 1300 may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

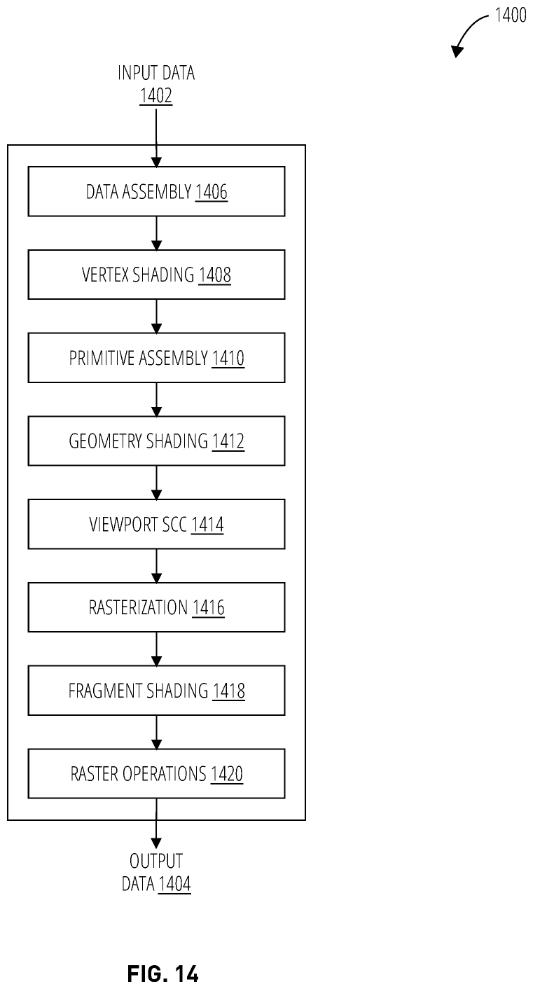

FIG. 14 is a conceptual diagram of a graphics processing pipeline 1400 implemented by the parallel processing unit 1208b of FIG. 8, in accordance with an embodiment. In an embodiment, the parallel processing unit 1208b comprises a graphics processing unit (GPU). The parallel processing unit 1208b is configured to receive commands that specify shader programs for processing graphics data. Graphics data may be defined as a set of primitives such as points, lines, triangles, quads, triangle strips, and the like. Typically, a primitive includes data that specifies a number of vertices for the primitive (e.g., in a model-space coordinate system) as well as attributes associated with each vertex of the primitive. The parallel processing unit 1208b can be configured to process the graphics primitives to generate a frame buffer (e.g., pixel data for each of the pixels of the display).

An application writes model data for a scene (e.g., a collection of vertices and attributes) to a memory such as a system memory or memory 812. The model data defines each of the objects that may be visible on a display. The application then makes an API call to the driver kernel that requests the model data to be rendered and displayed. The driver kernel reads the model data and writes commands to the one or more streams to perform operations to process the model data. The commands may reference different shader programs to be implemented on the streaming multiprocessor 1100 modules of the parallel processing unit 1208b including one or more of a vertex shader, hull shader, domain shader, geometry shader, and a pixel shader. For example, one or more of the streaming multiprocessor 1100 modules may be configured to execute a vertex shader program that processes a number of vertices defined by the model data. In an embodiment, the different streaming multiprocessor 1100 modules may be configured to execute different shader programs concurrently. For example, a first subset of streaming multiprocessor 1100 modules may be configured to execute a vertex shader program while a second subset of streaming multiprocessor 1100 modules may be configured to execute a pixel shader program. The first subset of streaming multiprocessor 1100 modules processes vertex data to produce processed vertex data and writes the processed vertex data to the level two cache 1004 and/or the memory 812. After the processed vertex data is rasterized (e.g., transformed from three-dimensional data into two-dimensional data in screen space) to produce fragment data, the second subset of streaming multiprocessor 1100 modules executes a pixel shader to produce processed fragment data, which is then blended with other processed fragment data and written to the frame buffer in memory 812. The vertex shader program and pixel shader program may execute concurrently, processing different data from the same scene in a pipelined fashion until all of the model data for the scene has been rendered to the frame buffer. Then, the contents of the frame buffer are transmitted to a display controller for display on a display device.

The graphics processing pipeline 1400 is an abstract flow diagram of the processing steps implemented to generate 2D computer-generated images from 3D geometry data. As is well-known, pipeline architectures may perform long latency operations more efficiently by splitting up the operation into a plurality of stages, where the output of each stage is coupled to the input of the next successive stage. Thus, the graphics processing pipeline 1400 receives input data 601 that is transmitted from one stage to the next stage of the graphics processing pipeline 1400 to generate output data 1404. In an embodiment, the graphics processing pipeline 1400 may represent a graphics processing pipeline defined by the OpenGL® API. As an option, the graphics processing pipeline 1400 may be implemented in the context of the functionality and architecture of the previous Figures and/or any subsequent Figure(s).

As shown in FIG. 14, the graphics processing pipeline 1400 comprises a pipeline architecture that includes a number of stages. The stages include, but are not limited to, a data assembly 1406 stage, a vertex shading 1408 stage, a primitive assembly 1410 stage, a geometry shading 1412 stage, a viewport SCC 1414 stage, a rasterization 1416 stage, a fragment shading 1418 stage, and a raster operations 1420 stage. In an embodiment, the input data 1402 comprises commands that configure the processing units to implement the stages of the graphics processing pipeline 1400 and geometric primitives (e.g., points, lines, triangles, quads, triangle strips or fans, etc.) to be processed by the stages. The output data 1404 may comprise pixel data (e.g., color data) that is copied into a frame buffer or other type of surface data structure in a memory.

The data assembly 1406 stage receives the input data 1402 that specifies vertex data for high-order surfaces, primitives, or the like. The data assembly 1406 stage collects the vertex data in a temporary storage or queue, such as by receiving a command from the host processor that includes a pointer to a buffer in memory and reading the vertex data from the buffer. The vertex data is then transmitted to the vertex shading 1408 stage for processing.

The vertex shading 1408 stage processes vertex data by performing a set of operations (e.g., a vertex shader or a program) once for each of the vertices. Vertices may be, e.g., specified as a 4-coordinate vector (e.g., <x, y, z, w>) associated with one or more vertex attributes (e.g., color, texture coordinates, surface normal, etc.). The vertex shading 1408 stage may manipulate individual vertex attributes such as position, color, texture coordinates, and the like. In other words, the vertex shading 1408 stage performs operations on the vertex coordinates or other vertex attributes associated with a vertex. Such operations commonly including lighting operations (e.g., modifying color attributes for a vertex) and transformation operations (e.g., modifying the coordinate space for a vertex). For example, vertices may be specified using coordinates in an object-coordinate space, which are transformed by multiplying the coordinates by a matrix that translates the coordinates from the object-coordinate space into a world space or a normalized-device-coordinate (NCD) space. The vertex shading 1408 stage generates transformed vertex data that is transmitted to the primitive assembly 1410 stage.

The primitive assembly 1410 stage collects vertices output by the vertex shading 1408 stage and groups the vertices into geometric primitives for processing by the geometry shading 1412 stage. For example, the primitive assembly 1410 stage may be configured to group every three consecutive vertices as a geometric primitive (e.g., a triangle) for transmission to the geometry shading 1412 stage. In some embodiments, specific vertices may be reused for consecutive geometric primitives (e.g., two consecutive triangles in a triangle strip may share two vertices). The primitive assembly 1410 stage transmits geometric primitives (e.g., a collection of associated vertices) to the geometry shading 1412 stage.

The geometry shading 1412 stage processes geometric primitives by performing a set of operations (e.g., a geometry shader or program) on the geometric primitives. Tessellation operations may generate one or more geometric primitives from each geometric primitive. In other words, the geometry shading 1412 stage may subdivide each geometric primitive into a finer mesh of two or more geometric primitives for processing by the rest of the graphics processing pipeline 1400. The geometry shading 1412 stage transmits geometric primitives to the viewport SCC 1414 stage.

In an embodiment, the graphics processing pipeline 1400 may operate within a streaming multiprocessor and the vertex shading 1408 stage, the primitive assembly 1410 stage, the geometry shading 1412 stage, the fragment shading 1418 stage, and/or hardware/software associated therewith, may sequentially perform processing operations. Once the sequential processing operations are complete, in an embodiment, the viewport SCC 1414 stage may utilize the data. In an embodiment, primitive data processed by one or more of the stages in the graphics processing pipeline 1400 may be written to a cache (e.g. L1 cache, a vertex cache, etc.). In this case, in an embodiment, the viewport SCC 1414 stage may access the data in the cache. In an embodiment, the viewport SCC 1414 stage and the rasterization 1416 stage are implemented as fixed function circuitry.

The viewport SCC 1414 stage performs viewport scaling, culling, and clipping of the geometric primitives. Each surface being rendered to is associated with an abstract camera position. The camera position represents a location of a viewer looking at the scene and defines a viewing frustum that encloses the objects of the scene. The viewing frustum may include a viewing plane, a rear plane, and four clipping planes. Any geometric primitive entirely outside of the viewing frustum may be culled (e.g., discarded) because the geometric primitive will not contribute to the final rendered scene. Any geometric primitive that is partially inside the viewing frustum and partially outside the viewing frustum may be clipped (e.g., transformed into a new geometric primitive that is enclosed within the viewing frustum. Furthermore, geometric primitives may each be scaled based on a depth of the viewing frustum. All potentially visible geometric primitives are then transmitted to the rasterization 1416 stage.

The rasterization 1416 stage converts the 3D geometric primitives into 2D fragments (e.g. capable of being utilized for display, etc.). The rasterization 1416 stage may be configured to utilize the vertices of the geometric primitives to setup a set of plane equations from which various attributes can be interpolated. The rasterization 1416 stage may also compute a coverage mask for a plurality of pixels that indicates whether one or more sample locations for the pixel intercept the geometric primitive. In an embodiment, z-testing may also be performed to determine if the geometric primitive is occluded by other geometric primitives that have already been rasterized. The rasterization 1416 stage generates fragment data (e.g., interpolated vertex attributes associated with a particular sample location for each covered pixel) that are transmitted to the fragment shading 1418 stage.

The fragment shading 1418 stage processes fragment data by performing a set of operations (e.g., a fragment shader or a program) on each of the fragments. The fragment shading 1418 stage may generate pixel data (e.g., color values) for the fragment such as by performing lighting operations or sampling texture maps using interpolated texture coordinates for the fragment. The fragment shading 1418 stage generates pixel data that is transmitted to the raster operations 1420 stage.

The raster operations 1420 stage may perform various operations on the pixel data such as performing alpha tests, stencil tests, and blending the pixel data with other pixel data corresponding to other fragments associated with the pixel. When the raster operations 1420 stage has finished processing the pixel data (e.g., the output data 1404), the pixel data may be written to a render target such as a frame buffer, a color buffer, or the like.

It will be appreciated that one or more additional stages may be included in the graphics processing pipeline 1400 in addition to or in lieu of one or more of the stages described above. Various implementations of the abstract graphics processing pipeline may implement different stages. Furthermore, one or more of the stages described above may be excluded from the graphics processing pipeline in some embodiments (such as the geometry shading 1412 stage). Other types of graphics processing pipelines are contemplated as being within the scope of the present disclosure. Furthermore, any of the stages of the graphics processing pipeline 1400 may be implemented by one or more dedicated hardware units within a graphics processor such as parallel processing unit 1208b. Other stages of the graphics processing pipeline 1400 may be implemented by programmable hardware units such as the streaming multiprocessor 1100 of the parallel processing unit 1208b.

The graphics processing pipeline 1400 may be implemented via an application executed by a host processor, such as a CPU. In an embodiment, a device driver may implement an application programming interface (API) that defines various functions that can be utilized by an application in order to generate graphical data for display. The device driver is a software program that includes a plurality of instructions that control the operation of the parallel processing unit 1208b. The API provides an abstraction for a programmer that lets a programmer utilize specialized graphics hardware, such as the parallel processing unit 1208b, to generate the graphical data without requiring the programmer to utilize the specific instruction set for the parallel processing unit 1208b. The application may include an API call that is routed to the device driver for the parallel processing unit 1208b. The device driver interprets the API call and performs various operations to respond to the API call. In some instances, the device driver may perform operations by executing instructions on the CPU. In other instances, the device driver may perform operations, at least in part, by launching operations on the parallel processing unit 1208b utilizing an input/output interface between the CPU and the parallel processing unit 1208b. In an embodiment, the device driver is configured to implement the graphics processing pipeline 1400 utilizing the hardware of the parallel processing unit 1208b.

Various programs may be executed within the parallel processing unit 1208b in order to implement the various stages of the graphics processing pipeline 1400. For example, the device driver may launch a kernel on the parallel processing unit 1208b to perform the vertex shading 1408 stage on one streaming multiprocessor 1100 (or multiple streaming multiprocessor 1100 modules). The device driver (or the initial kernel executed by the parallel processing unit 1208b) may also launch other kernels on the parallel processing unit 1208b to perform other stages of the graphics processing pipeline 1400, such as the geometry shading 1412 stage and the fragment shading 1418 stage. In addition, some of the stages of the graphics processing pipeline 1400 may be implemented on fixed unit hardware such as a rasterizer or a data assembler implemented within the parallel processing unit 1208b. It will be appreciated that results from one kernel may be processed by one or more intervening fixed function hardware units before being processed by a subsequent kernel on a streaming multiprocessor 1100.

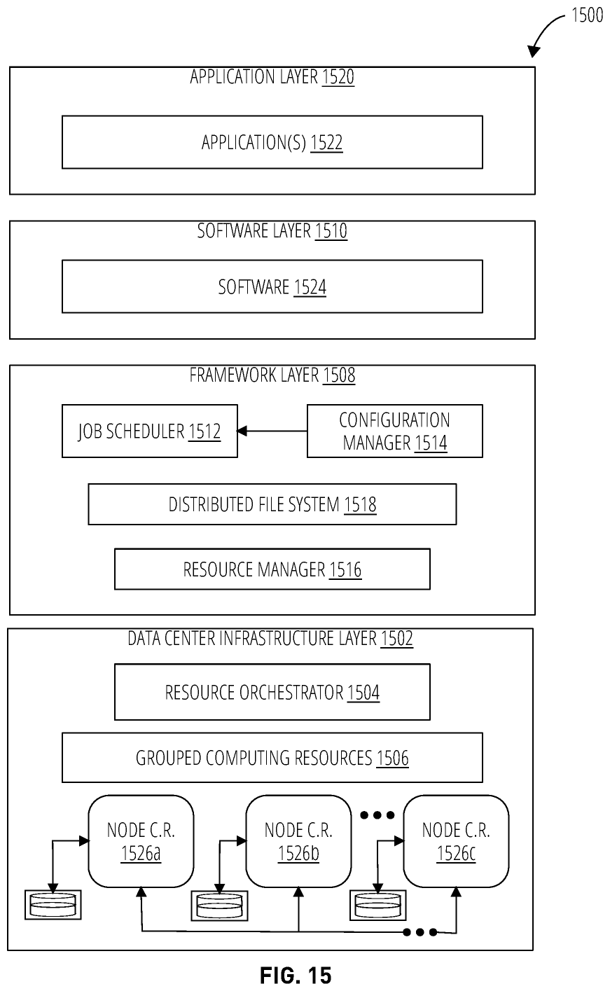

FIG. 15 depicts an exemplary data center 1500, in accordance with at least one embodiment. The data center 1500 may utilize embodiments of the circuits described herein, for example in data transceivers or any circuit in which the reference spur in a signal is advantageously reduced. In at least one embodiment, data center 1500 includes, without limitation, a data center infrastructure layer 1502, a framework layer 1508, software layer 1510, and an application layer 1520.

In at least one embodiment, as depicted in FIG. 15, data center infrastructure layer 1502 may include a resource orchestrator 1504, grouped computing resources 1506, and node computing resources (“node C.R.s”) Node C.R. 1526a, Node C.R. 1526b, Node C.R. 1526c, . . . node C.R. N), where “N” represents any whole, positive integer. In at least one embodiment, node C.R.s may include, but are not limited to, any number of central processing units (“CPUs”) or other processors (including accelerators, field programmable gate arrays (“FPGAs”), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s may be a server having one or more of above-mentioned computing resources.

In at least one embodiment, grouped computing resources 1506 may include separate groupings of node C.R.s housed within one or more racks (not shown), or many racks housed in data centers at various geographical locations (also not shown). Separate groupings of node C.R.s within grouped computing resources 1506 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1504 may configure or otherwise control one or more node C.R.s and/or grouped computing resources 1506. In at least one embodiment, resource orchestrator 1504 may include a software design infrastructure (“SDI”) management entity for data center 1500. In at least one embodiment, resource orchestrator 1504 may include hardware, software or some combination thereof.

In at least one embodiment, as depicted in FIG. 15, framework layer 1508 includes, without limitation, a job scheduler 1512, a configuration manager 1514, a resource manager 1516, and a distributed file system 1518. In at least one embodiment, framework layer 1508 may include a framework to support software 1524 of software layer 1510 and/or one or more application(s) 1522 of application layer 220. In at least one embodiment, software 1524 or application(s) 1522 may respectively include web-based service software or applications, such as those provided by Amazon Web Services, Google Cloud and Microsoft Azure. In at least one embodiment, framework layer 1508 may be, but is not limited to, a type of free and open-source software web application framework such as Apache Spark™ (hereinafter “Spark”) that may utilize a distributed file system 1518 for large-scale data processing (e.g., “big data”). In at least one embodiment, job scheduler 1512 may include a Spark driver to facilitate scheduling of workloads supported by various layers of data center 1500. In at least one embodiment, configuration manager 1514 may be capable of configuring different layers such as software layer 1510 and framework layer 1508, including Spark and distributed file system 1518 for supporting large-scale data processing. In at least one embodiment, resource manager 1516 may be capable of managing clustered or grouped computing resources mapped to or allocated for support of distributed file system 1518 and distributed file system 1518. In at least one embodiment, clustered or grouped computing resources may include grouped computing resources 1506 at data center infrastructure layer 1502. In at least one embodiment, resource manager 1516 may coordinate with resource orchestrator 1504 to manage these mapped or allocated computing resources.

In at least one embodiment, software 1524 included in software layer 1510 may include software used by at least portions of node C.R.s, grouped computing resources 1506, and/or distributed file system 1518 of framework layer 1508. One or more types of software may include, but are not limited to, Internet web page search software, e-mail virus scan software, database software, and streaming video content software.

In at least one embodiment, application(s) 1522 included in application layer 1520 may include one or more types of applications used by at least portions of node C.R.s, grouped computing resources 1506, and/or distributed file system 1518 of framework layer 1508. In at least one or more types of applications may include, without limitation, CUDA applications, 5G network applications, artificial intelligence application, data center applications, and/or variations thereof.

In at least one embodiment, any of configuration manager 1514, resource manager 1516, and resource orchestrator 1504 may implement any number and type of self-modifying actions based on any amount and type of data acquired in any technically feasible fashion. In at least one embodiment, self-modifying actions may relieve a data center operator of data center 1500 from making possibly bad configuration decisions and possibly avoiding underutilized and/or poor performing portions of a data center.

### LISTING OF DRAWING ELEMENTS

100 conventional clock calibration circuit

102 phase/frequency detector

104 charge pump

106 voltage controlled oscillator

108 frequency divider

110 resistor

112 capacitor

202 circuit system

204 computing system

206 vehicle

208 robot

300 data transceiver

302 transmitter

304 receiver

306 clock

308 phase calibration circuit

400 clock recovery circuit

402 phase locked loop

404 transmission line clock receiver

406 frequency divider

408 termination circuit

410 continuous-time linear amplifier

412 variable gain amplifier

414 analog-to-digital converter

416 state machine logic

418 digitally controlled oscillator

420 clock delay buffer

500 clock calibration circuit

502 phase/frequency detector

504 charge pump

506 current controlled oscillator

508 frequency divider

510 capacitor

512 charge pump

514 reset-sample-hold circuit

516 voltage-to-current converter

518 voltage-to-current converter

520 capacitor

522 voltage controlled oscillator

524 switched capacitive circuit

600 switched capacitive circuit

602 capacitor

604 capacitor

606 comparator

608 sample switch s₁

610 reset switch r₁

612 hold switch h₁

614 reset switch r₂

616 sample switch s₂

618 hold switch h₂

700 signal timing diagram

802 I/O unit

804 front-end unit

806 hub

808 scheduler unit

810 work distribution unit

812 memory

814 crossbar

816 NVLink

818 interconnect

900 general processing cluster

902 pipeline manager

904 pre-raster operations unit

906 data processing cluster

908 raster engine

910 M-pipe controller

912 primitive engine

914 work distribution crossbar

916 memory management unit

1000 memory partition unit

1002 raster operations unit

1004 level two cache

1006 memory interface

1100 streaming multiprocessor

1102 instruction cache

1104 scheduler unit

1106 dispatch

1108 register file

1110 core

1112 special function unit

1114 load/store unit

1116 interconnect network

1118 shared memory/L1 cache

1200 processing system

1202 parallel processing module

1204 switch

1206 central processing unit

1208a parallel processing unit

1208b parallel processing unit

1208c parallel processing unit

1208d parallel processing unit

1300 exemplary processing system

1302 main memory

1304 network interface

1306 display devices

1308 input devices

1310 communications bus

1400 graphics processing pipeline

1402 input data

1404 output data

1406 data assembly

1408 vertex shading

1410 primitive assembly

1412 geometry shading

1414 viewport SCC

1416 rasterization

1418 fragment shading

1420 raster operations

1500 data center

1502 data center infrastructure layer

1504 resource orchestrator

1506 grouped computing resources

1508 framework layer

1510 software layer

1512 job scheduler

1514 configuration manager

1516 resource manager

1518 distributed file system

1520 application layer

1522 application(s)

1524 software

1526a node C.R.

1526b node C.R.

1526c node C.R.

“Inner node” refers to a node coupling two or more terminals of a circuit component.

“Integration path” refers to a circuit path with a transfer function dominated by capacitive effects.

“Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

“Proportional path” refers to a circuit path dominated by resistive effects.

“Reference spur” refers to a transient power spike in a signal.

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the invention as claimed. The scope of inventive subject matter is not limited to the depicted embodiments but is rather set forth in the following Claims.

What is claimed is:

1. A circuit comprising:
a plurality of charge pumps;
a voltage controlled oscillator;
an integration path from a first one of the charge pumps to the voltage controlled oscillator; and
a proportional path from a second one of the charge pumps to the voltage controlled oscillator.

2. The circuit of claim 1, wherein the proportional path comprises a switched capacitive circuit.

3. The circuit of claim 2, the switched capacitive circuit comprising:
a plurality of reset switches;
a plurality of sample switches; and
a plurality of hold switches.

4. The circuit of claim 2, wherein the switched capacitive circuit comprises a parallel configuration of sample and hold switches.

5. The circuit of claim 2, further comprising:
a reset-sample-hold circuit configured to control the switched capacitive circuit.

6. The circuit of claim 1, further comprising:
a first voltage-to-current converter configured on the integration path; and
a second voltage-to-current converter configured on the proportional path.

7. The circuit of claim 6, wherein outputs of the first voltage-to-current converter and the second voltage-to-current converter are merged into a current controlled oscillator.

8. A phase locked loop comprising:
a first charge pump;
a second charge pump;
a voltage controlled oscillator;
a first path dominated by capacitive effects from the first charge pump to the voltage controlled oscillator;
a second path dominated by resistive effects from the second charge pump to the voltage controlled oscillator; and
the charge pumps configured to output different valued currents on the first path and the second path during operation of the circuit.

9. The phase locked loop of claim 8, wherein the first path comprises a switched capacitive circuit.

10. The phase locked loop of claim 9, the switched capacitive circuit comprising a plurality of sample switches shunted by a plurality of reset switches.

11. The phase locked loop of claim 9, wherein the switched capacitive circuit comprises an inner node coupled to a reference voltage comparator.

12. The phase locked loop of claim 9, further comprising:
a reset-sample-hold circuit configured to control the switched capacitive circuit.

13. The phase locked loop of claim 8, further comprising:
a first voltage-to-current converter configured on the first path; and
a second voltage-to-current converter configured on the second path.

14. The phase locked loop of claim 13, wherein outputs of the first voltage-to-current converter and the second voltage-to-current converter are combined at an input of a current controlled oscillator.

15. A transceiver comprising:
a data transmitting circuit;
a data receiving circuit coupled to receive data signals from the transmitting circuit;
one or more clock signal generators coupled to one or both of the transmitting circuit and the receiving circuit;
one or more clock calibration circuits coupled to the one or more clock signal generators, at least one of the clock calibration circuits comprising:
a plurality of charge pumps; and
a voltage controlled oscillator configured to receive current from both of an integration path from a first one of the charge pumps and a proportional path from a second one of the charge pumps.

16. The transceiver of claim 15, wherein the proportional path comprises a switched capacitive circuit.

17. The transceiver of claim 16, the switched capacitive circuit comprising a series-parallel configuration of switches.

18. The transceiver of claim 16, further comprising:
a reset-sample-hold circuit configured to control the switched capacitive circuit.

19. The transceiver of claim 15, further comprising:
a first gain circuit configured on the integration path; and
a second gain circuit configured on the proportional path.

20. The transceiver of claim 19, wherein outputs of the first gain circuit and the second gain circuit are merged.
